(19) United States
(12) Patent Application Publication
(10) Pub. No.: US 2014/0360770 A1
(43) Pub. Date: Dec. 11, 2014

(54) PRINTED CIRCUIT BOARD

(71) Applicant: HON HAI PRECISION INDUSTRY CO., LTD., New Taipei (TW)

(72) Inventors: WEN-CHIEH TSAI, New Taipei (TW); FANG-YI LIN, New Taipei (TW)

(21) Appl. No.: 13/926,056

(22) Filed: Jun. 25, 2013

(30) Foreign Application Priority Data
Jun. 5, 2013 (TW) 102120006

(51) Int. Cl. H05K 1/11

(52) U.S. Cl. CPC H05K 1/116
USPC 174/262

(57) ABSTRACT

An exemplary printed circuit board includes a planar base, a first signal via defined in the base, a second signal via defined in the base, a first ground via defined in the base adjacent to the first signal via, a second ground via defined in the base adjacent to the second signal via, a first through hole defined in the base between the first signal via and the first ground via, and a second through hole defined in the base between the second signal via and the second ground via.

### BACKGROUND

1. Technical Field

The present disclosure relates to printed circuit boards, more particularly to a printed circuit board incorporating at least a signal via and a ground via.

2. Description of Related Art

Via hole design is an important phase in the design of a printed circuit board (PCB). A via stub may be generated when the PCB has a plurality of layers.

Generally, there are two common methods for removing via stubs. One is a technique of manufacturing buried via holes to remove the via stubs. Another is a back-drilling technique to remove the via stubs. However, the cost of production is increases, and the back-drilling technique is difficult to perform.

What is needed, therefore, is an improved printed circuit board which overcomes the above described shortcomings.

### BRIEF DESCRIPTION OF THE DRAWINGS

FIG. 1 is an isometric, schematic view of a printed circuit board according to an exemplary embodiment of the present disclosure.

FIG. 2 is a top view of the printed circuit board of FIG. 1.

### DETAILED DESCRIPTION

An embodiment of a printed circuit board in accordance with the present disclosure will now be described in detail below and with reference to the drawings.

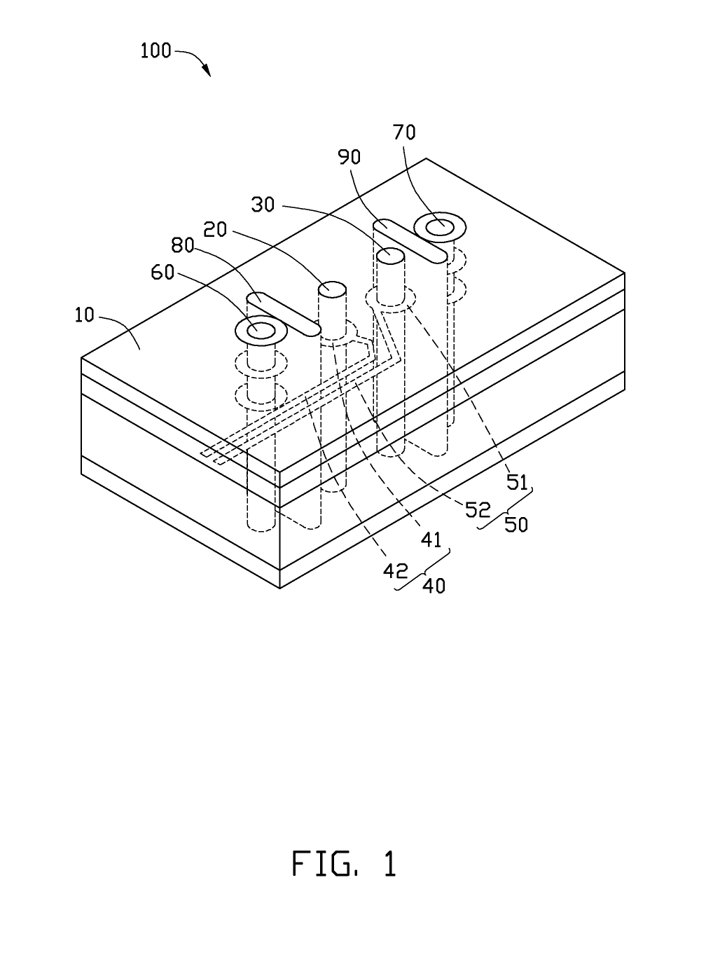

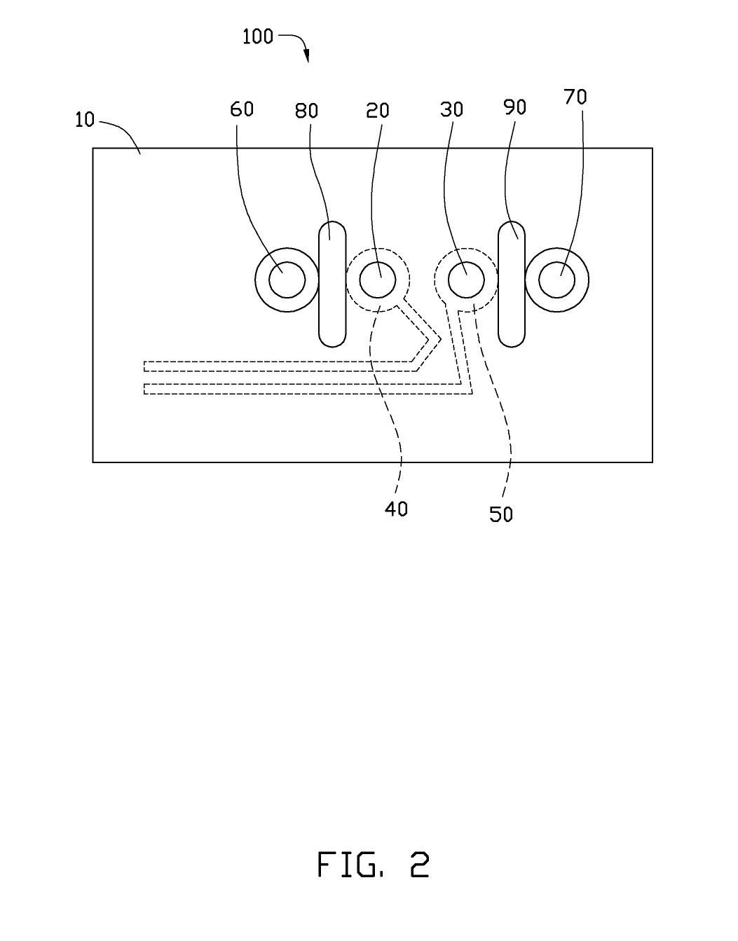

Referring to FIGS. 1-2, a printed circuit board 100 in accordance with an exemplary embodiment of the disclosure is illustrated. The printed circuit board 100 includes a planar base 10, a first signal via 20 defined in and extending through the base 10, a second signal via 30 defined in and extending through the base 10, a first differential trace 40 extending outwardly from the first signal via 20, a second differential trace 50 extending outwardly from the second signal via 30, a first ground via 60 defined in and extending through the base 10 adjacent to the first signal via 20, a second via 70 defined in and extending through the base 10 adjacent to the second signal via 30, a first through hole 80 defined in the base 10 and located between the first signal via 20 and the first ground via 60, and a second through hole 90 defined in the base 10 and located between the second signal via 30 and the second ground via 70.

In this embodiment of the disclosure, the first signal via 20, the second signal via 30, the first ground via 60 and the second ground via 70 are all round holes, and the first through hole 80 and the second through hole 90 are slotted holes. In dimension, the first through hole 80 and the second through hole 90 are larger than the first signal via 20, the second signal via 30, the first ground via 60 and the second ground via 70. The first signal via 20, the second signal via 30, the first ground via 60, the second ground via 70, the first through hole 80 and the second through hole 90 all extend vertically from a bottom/top face to a top/bottom face of the base 10. A geometrical center of the first through hole 80 is aligned with that of the first signal via 20 and that of the first ground via 60. A geometrical center of the second through hole 90 is aligned with that of the second signal via 30 and that of the second ground via 70. A distance between the first signal via 20 and the first ground via 60 is equal to that between the second signal via 30 and the second ground via 70. The first signal via 20 is spaced from the first ground via 60 by the first through hole 80. The second signal via 30 is spaced from the second ground via 70 by the second through hole 90.

The first differential trace 40 includes an annular first cap 41 surrounding the first signal via 20, and a first transmitting segment 42 extending outwardly and transversely from the first cap 41. The first signal via 20 is electrically connected to the first cap 41 of the first differential trace 40.

The second differential trace 50 includes an annular second cap 51 surrounding the second signal via 30, and a second transmitting segment 52 extending outwardly and transversely from the second cap 51. The second signal via 30 is electrically connected to the second cap 51 of the second differential trace 50.

The base 10 is a multilayer structure. The first differential trace 40 and the second differential trace 50 both could extend along different layers of the base 10, such as the top face of the base 10, the bottom face of the base 10, or a middle layer of the base 10. In this embodiment of the disclosure, the first differential trace 40 and the second differential trace 50 extend along the middle layer of the base 10.

In use, the first through hole 80 is formed between the first signal via 20 and the first ground via 60, and the first signal via 20 is spaced from the first ground via 60 by the first through hole 80; the second through hole 90 is formed between the second signal via 30 and the second ground via 70, and the second signal via 30 is spaced from the second ground via 70 by the second through hole 90, thereby effectively decreasing the equivalent permittivity of capacitance and decreasing the equivalent capacitance, and optimizing the performance of the printed circuit board 100. In result, for the printed circuit board 100 of the present disclosure, it doesn't need to remove the via stubs.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A printed circuit board comprising:
a planar base;
a first signal via defined in the base;
a second signal via defined in the base;
a first ground via defined in the base adjacent to the first signal via;
a second ground via defined in the base adjacent to the second signal via;
a first through hole defined in the base between the first signal via and the first ground via; and
a second through hole defined in the base between the second signal via and the second ground via.

2. The printed circuit board as claimed in claim 1, wherein a geometrical center of the first through hole is aligned with that of the first signal via and that of the first ground via.

3. The printed circuit board as claimed in claim 1, wherein a geometrical center of the second through hole is aligned with that of the second signal via and that of the second ground via.

4. The printed circuit board as claimed in claim 1, wherein a distance between the first signal via and the first ground via is equal to that between the second signal via and the second ground via.

5. The printed circuit board as claimed in claim 1, wherein the first signal via is spaced from the first ground via by the first through hole.

6. The printed circuit board as claimed in claim 1, wherein the second signal via is spaced from the second ground via by the second through hole.

7. The printed circuit board as claimed in claim 1, wherein the first signal via, the second signal via, the first ground via and the second ground via are all round holes.

8. The printed circuit board as claimed in claim 1, wherein the first through hole and the second through hole are slotted holes.

9. The printed circuit board as claimed in claim 1, wherein in dimension, the first through hole is larger than the first signal via and the first ground via, the second through hole is larger than the second signal via and the second ground via.

10. The printed circuit board as claimed in claim 1, wherein the first through hole and the second through hole extend from a bottom face of the base to a top face of the base.

11. The printed circuit board as claimed in claim 1, further comprising a first differential trace extending outwardly from the first signal via, and a second differential trace extending outwardly from the second signal via.

12. The printed circuit board as claimed in claim 11, wherein the first differential trace comprises an annular first cap surrounding the first signal via, and a first transmitting segment extending outwardly from the first cap.

13. The printed circuit board as claimed in claim 11, wherein the second differential trace comprises an annular second cap surrounding the second signal via, and a second transmitting segment extending outwardly from the second cap.

14. The printed circuit board as claimed in claim 11, wherein the base is a multilayer structure.

15. The printed circuit board as claimed in claim 14, wherein the first differential trace and the second differential trace extend transversely along a middle layer of the base.
